(19) United States
(12) Patent Application Publication
(10) Pub. No.: US 2026/0271407 A1
(43) Pub. Date: Sep. 10, 2026

(54) POWER FET WITH FAIL-OPEN SAFETY FEATURE

(71) Applicant: Microchip Technology Incorporated, Chandler, AZ (US)

(72) Inventors: Andrei Bucsa, GILBERT, AZ (US); Shesh Mani Pandey, Gilbert, AZ (US)

(73) Assignee: Microchip Technology Incorporated, Chandler, AZ (US)

(21) Appl. No.: 19/435,998

(22) Filed: Dec. 30, 2025

Related U.S. Application Data
(60) Provisional application No. 63/769,470, filed on Mar. 10, 2025.

(51) Int. Cl. H10D 89/60; H10D 30/66

(52) U.S. Cl. CPC H10D 89/911; H10D 30/668; H10D 89/931

(57) ABSTRACT

A field-effect transistor with a fail-open safety feature. A ferroic bridge extends between a source and a gate. The ferroic bridge includes a ferroic material that is in an electrically non-conducting state below a threshold temperature and in an electrically conducting state at and above the threshold temperature. When the ferroic bridge reaches the threshold temperature, the material switches to the electrically conducting state which electrically connects the source and the gate and restricts an electrical current from flowing through the field-effect transistor. The threshold temperature may be above a normal operating temperature and below a critical temperature at which a structural failure may occur. A reset terminal may allow for applying a reset signal that switches the ferroic material back to the non-conductive state to allow the current to resume flowing. The electrical signal may be applied perpendicular to a polarization of the ferroic bridge.

### RELATED APPLICATION

The present U.S. non-provisional patent application is related to and claims priority benefit of an earlier-filed U.S. provisional patent application titled "Power FET with Fail-Open Safety Feature," Serial No. 63/769,470, filed March 10, 2025. The entire content of the identified earlier-filed application is incorporated by reference as if fully set forth herein.

### FIELD

The present disclosure relates to field-effect transistors and methods of making them, and more particularly, the various examples described herein concern a power field-effect transistor with a fail-open safety feature, and a method of making a field-effect transistor with a fail-open safety feature.

### BACKGROUND

A metal-oxide-semiconductor field-effect transistor (MOSFET) is an active, voltage-controlled semiconductor device, in which varying an electrical voltage between a gate and a body controls an electrical current flowing through a semiconductor channel between a drain and a source. Applications for MOSFETs include amplifiers, switches, resistors, regulators, oscillators, and choppers. It is generally desirable to improve the performance and reduce the cost of MOSFETs, but it can be difficult to do so.

This background discussion is intended to provide related information, and is not necessarily prior art.

### SUMMARY

Examples provide a power MOSFET with a fail-open safety feature, and a method of making a power MOSFET with a fail-open safety feature. Broadly, the power MOSFET always fails open during thermal runaway when a threshold temperature is exceeded. In some examples, the fail-open condition is reversible so that the device can be reset to its functional state. Examples advantageously eliminate the need for a shared safety fuse or other shared safety circuitry for transistor thermal protection, which avoids the loss of power to other branches, and thereby improve performance and lower costs.

In an example, a field-effect transistor (FET) may include a source, a gate, and a ferroic bridge. The ferroic bridge may be electrically and thermally coupled with the source and the gate, and the ferroic bridge may switch from an electrically non-conducting state to an electrically conducting state at a threshold temperature to thereby electrically connect the source and the gate and restrict an electrical current from flowing through the FET.

In another example, a MOSFET device may include a MOSFET and reset terminal. The MOSFET may include volume of semiconductor material, a source, a drain, a channel, a gate, and a ferroic bridge. The source may be located at a first end of the volume of semiconductor material and through which charge carriers enter. The drain may be located spaced apart from the source and through which the charge carriers exit. The channel may be located between the source and the drain through which the charge carriers move between the source and the drain. The gate may be located at the first end of the volume of semiconductor material used in controlling movement of the charge carriers through the channel. The ferroic bridge may be electrically coupled with the source and the gate. The ferroic bridge may include a ferroic material that is in an electrically non-conducting state below a threshold temperature and in an electrically conducting state at and above the threshold temperature, such that when the ferroic bridge reaches the threshold temperature the ferroic material switches to the electrically conducting state to thereby electrically connect the source and the gate and restrict the charge carriers from moving and an electrical current from flowing between the source and the drain. The reset terminal may be electrically connected to the ferroic bridge and configured to apply a reset signal that switches the ferroic bridge from the electrically conductive state to the electrically non-conductive state to thereby permit the charge carriers to move and the electrical current flow between the source and the drain.

In another example, a method for making a FET may include the following operations. A source and a gate may be formed. A ferroic bridge may be inserted so as to be electrically and thermally coupled with the source and the gate. The ferroic bridge may switch from an electrically non-conducting state to an electrically conducting state at a threshold temperature to thereby electrically connect the source and the gate and restrict an electrical current from flowing through the FET.

Each of the preceding examples may further include any one or more of the following features.

The ferroic material may be in an electrically non-conducting amorphous state below the threshold temperature, and in an electrically conducting crystalline state at and above the threshold temperature. The FET may have a trench configuration. In various examples, a volume of semiconductor may present a trench in which the gate is at least partially located. The ferroic bridge may include a ferroic material such as indium (III) selenide (In₂Se₃), bis(tellanylidene)molybdenum (MoTe₂), tin(II) sulfide (SnS), perovskite (CaTiO₃), poly(1,1-difluoroethylene) (C₂H2F₂), hafnium(IV) oxide (HfO₂), tin telluride (SnTe), germanium selenide (GeSe), copper indium phosphorous sulfide (CuInP₂S₆), bismuth oxide selenide (Bi₂O₂Se), and combinations thereof. The ferroic material may be doped with a dopant such as zinc (ZN), silicon dioxide (SiO₂), titanium (Ti), nitrogen (N), antimony (Sb), sulfur (S), and combinations thereof. The threshold temperature may be above a normal operating temperature of the FET (or MOSFET) and below a critical temperature at which a structural failure of the FET (or MOSFET) occurs. The FET may further be associated with a reset terminal electrically connected to the ferroic bridge and configured to apply a reset signal that switches the ferroic bridge from the electrically conducting state to the electrically non-conducting state to thereby allow the electrical current to flow through the FET. The reset signal may be applied perpendicular to a polarization of the ferroic bridge. The FET may be associated (or the MOSFET device may include) a gate-driving circuit and a microcontroller. The gate-driving circuit may drive the gate and may send an electrical interrupt signal when the ferroic material switches to the electrically conducting state to thereby electrically connect the source and the gate. The microcontroller may receive the electrical interrupt signal from the gate-driving circuit and send the reset signal to the reset terminal.

This summary is not intended to identify essential features of the examples, and is not intended to be used to limit the scope of the claims. These and other aspects of the present examples are described below in greater detail.

### DRAWINGS

Examples are described in detail below with reference to the attached drawing figures, wherein:

FIG. 1 is a cross-sectional elevation view of a first example of a power MOSFET with a fail-open safety feature;

FIG. 2 is a cross-sectional elevation view of a second example of a power MOSFET with a reversible fail-open safety feature;

FIG. 3 is a cross-sectional elevation view of a third example of a trench MOSFET with a fail-open safety feature; and

FIG. 4 is a flowchart of steps in a method for making a power FET with a fail-open safety feature, such as the MOSFETs of FIGS. 1-3.

The figures are not intended to limit the examples to the specific details depict. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples. The illustrations presented herein are not meant to be actual views of any particular method, system, device, or structure, but are merely idealized representations that are employed to describe the examples of the present disclosure. Similar structures or components in the various drawings may retain the same or similar numbering for the convenience of the reader; however, any similarity in numbering does not necessarily mean that the structures or components are necessarily identical in size, composition, configuration, or any other property. Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation. It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

An obstacle for FETs, and more particularly MOSFETs, in solid-state switching applications with a high safety integrity level (SIL) is that the FET failure mode is uncertain outside of nominal conditions: A power FET can either fail open or fail short (i.e., short circuit). It is generally desirable that a FET always fail in a predictable, safe way to ensure the load is in a safe state. Conventionally, preventing short failures of FETs integrated into critical switching applications, such as motor control, inverters, and power supplies, requires complex circuitry to ensure device circuitry protection. For example, in a system that uses multiple MOSFET switches branched from the same power supply, and which is incorporated into a power distribution management/protection application, when a single load failure occurs, the corresponding MOSFET may fail short which results in a sustained high current through the shorted branch. As a result, a shared safety fuse will blow and all other branches, which may be operating normally, will lose power.

Examples provide a power FET with a fail-open safety feature for high SIL applications. Broadly, the example power FET always fails open (or latches OFF), independent of environmental conditions, during thermal runaway when a threshold temperature is exceeded. In some examples, the fail-open condition is reversible so that the power FET can be reset back to the functional state by applying an electric field to a reset terminal or gate. The latching status may be monitored by monitoring the gate current, so the driver circuitry signals a latching state to the controlling microcontroller. Because the example power FET will always fail open, there is no need for a shared safety fuse or other shared safety circuitry for transistor thermal protection, which avoids the loss of power to other branches. Thus, by simplifying the driving and protection scheme, examples advantageously improve performance and lower costs. Potential applications include safety applications in which FETs are used as solid-state relays (i.e., eFuses), self-protecting switching devices (e.g., inverters, digital switching power supplies), optimized applications with intrinsic over-temperature self-protection, and, generally, power electronics applications that use FETs.

In more detail, when operating in nominal conditions, such as a gate voltage (Vg) voltage being over zero temperature coefficient (ZTC)) and under a drain-source voltage (Vds) avalanche threshold, conventional FETs sometimes fail to open because of aluminum diffusion. When this occurs, the gate is shorted to the source at a lower temperature than is required for the channel to melt and collapse. Ferroic materials, which have both ferroelectric and piezoelectric characteristics, switch from an electrically non-conductive amorphous state to an electrically conductive crystalline state at a threshold temperature which is dependent on the material, in a phenomenon known as "thermal annealing." Further, ferroic materials switch back to the electrically non-conductive amorphous state when a small electric field is applied perpendicular to the polarization. By doping a ferroic material (e.g., indium(III) selenide (In₂Se₃)) with a suitable dopant (e.g., zinc (Zn)), both the state switching speed and the switching temperature increase with the doping concentration. Thus, a ferroic material switches to a conductive state by thermal annealing at a threshold temperature and switches back to a non-conductive state by application of an electric field.

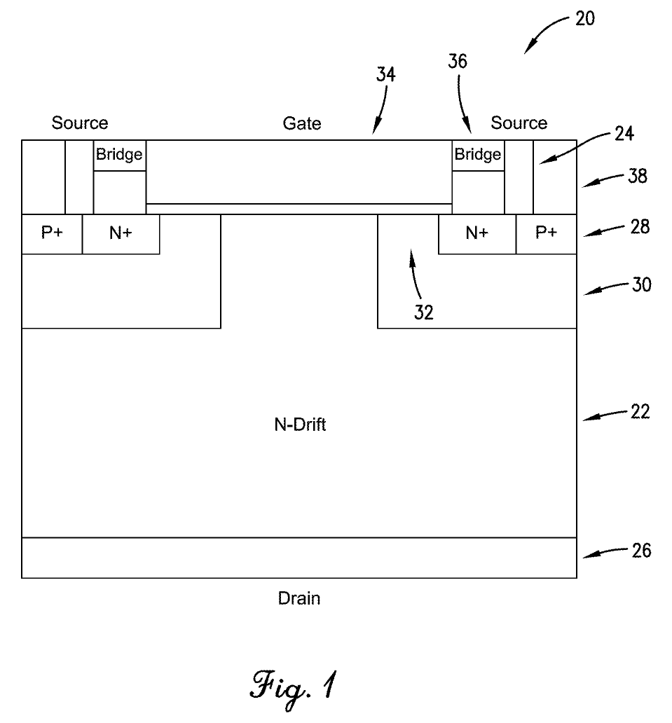

Referring to FIG. 1, a first example power MOSFET 20 with a fail-open safety feature is shown including a volume of semiconductor material 22, a source 24, a drain 26, a body 28, a well 30, a channel 32, a gate 34, and a ferroic bridge 36. In this and other example MOSFETs shown and described herein, the source, body, well, channel, and ferroic bridge may each include left and right instances located on opposite sides of the centrally located gate. However, these components and their materials, sizes, and positions may vary depending on the nature of and application for the device.

The volume of semiconductor material 22 may include a first end and a second end. The semiconductor material 22 may be or include silicon carbide (SiC). The source 24 may be located at the first end of the volume of semiconductor material 22 and may provide an entrance for charge carriers. The source 24 may be or include N+ material. The drain 26 may be located spaced apart from the source 24 (e.g., at the second end) and may provide an exit for the charge carriers. The drain may be or include an N+ substrate material. The body 28 may facilitate controlling the movement of charge carriers. The body 28 may be or include a P+ material. The well 30 may facilitate forming the channel 30. The well 30 may be or include P-type material. The channel 32 may be a region between the source 24 and the drain 26 through which the charge carriers move. The gate 34 may be located at the first end of the volume of semiconductor material 22 and facilitate controlling movement of the charge carriers through the channel 32. The gate 34 may be or include a dielectric material (e.g., silicon dioxide (SiO₂)) and a doped polysilicon material. Additional components may include a layer of electrically insulating material 38 over at least a portion of the first end of the volume of semiconductor material 22. Although, the first example power MOSFET 20 is shown in a planar configuration, the invention is not limited this particular configuration.

The ferroic bridge 36 may be located between and thermally and electrically coupled with the source 24 and the gate 34, and may include a ferroic material. The ferroic bridge 36 may be electrically isolated from other structures by, e.g. the layer or region of electrically insulating material 38. Broadly, the ferroic bridge 36 may be thermally coupled with the structure of the MOSFET 20, so that the temperature of the ferroic bridge 36 is similar to or the same as the operating temperature of the structure (and, more broadly, the overall operating temperature of the MOSFET 20). Such thermal coupling (whether it is with the source 24, gate 34, or other structure) may be by direct contact or via indirect thermal coupling (using, e.g., an interposed thermal conductor). In the illustrated example, the ferroic bridge 36 directly electrically connects to and engages the source 24 and the gate 34. Alternatively, an indirect electrical connection (via, e.g., a contact or other electrical conductor) may be provided between the ferroic bridge 32 and each (or either) of the source 24 and gate 34.

Broadly, when the ferroic bridge 32 reaches a threshold temperature, the ferroic bridge 32 may short the source 24 and the gate 34 and thereby open, or latch OFF, the MOSFET 20 to prevent current from flowing (or continuing to flow). The threshold temperature may be above a normal operating temperature of the MOSFET 20 and below a critical temperature at which a structural failure of the MOSFET 20 may occur. The ferroic material may be in an electrically non-conducting amorphous state below the threshold temperature and in an electrically conducting crystalline state at and above the threshold temperature. Example ferroic materials include indium (III) selenide (In2Se3), bis(tellanylidene)molybdenum (MoTe₂), tin(II) sulfide (SnS), perovskite (CaTiO₃), poly(1,1-difluoroethylene) (C₂H2F₂), hafnium(IV) oxide (HfO₂), tin telluride (SnTe), germanium selenide (GeSe), copper indium phosphorous sulfide (CuInP₂S₆) (also called "CIPS"), bismuth oxide selenide (Bi₂O₂Se), and combinations thereof. In some examples, the ferroic material may be undoped. In other examples, the ferroic material may be doped with a suitable dopant for changing the crystallization temperature of the ferroic material. Example dopants include ZN, silicon dioxide (SiO₂), titanium (Ti), nitrogen (N), antimony (Sb), and sulfur (S), and combinations thereof. The threshold temperature may depend on the ferroic material and, if present, the doping material and the doping percentage.

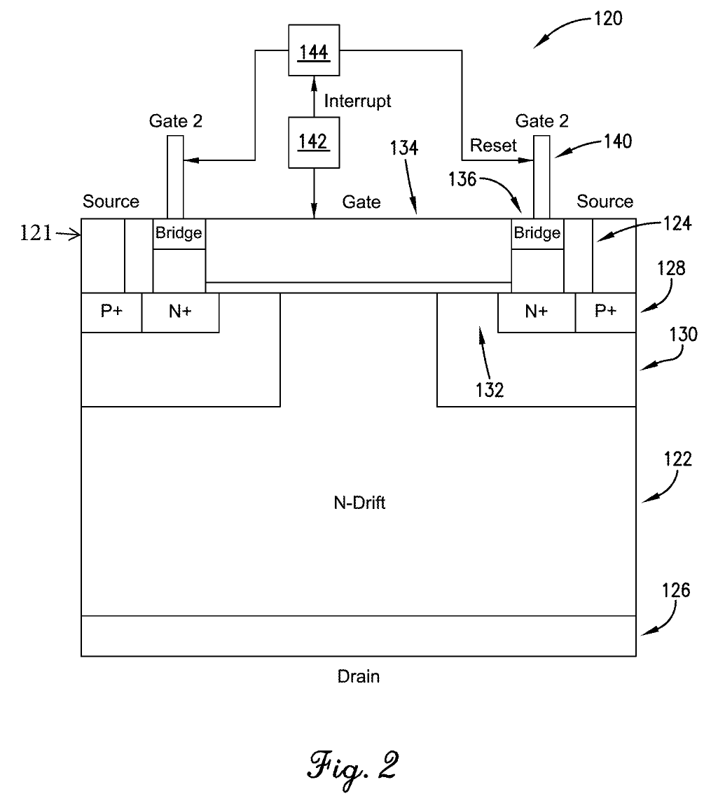

Referring to FIG. 2, a second example power MOSFET device 120 is shown with a reversible fail-open safety feature. The MOSFET device 120 may include a MOSFET 121 which may be substantially similar or identical to the first example MOSFET 20, including a volume of semiconductor material 122, a source 124, a drain 126, a body 128, a well 130, a channel 132, a gate 134, and a ferroic bridge 136 as described above. The MOSFET device may further include a reset terminal 140, a gate driving circuit 142, and a microcontroller 144. The reset terminal 140, or reset gate, may allow for reversing the open condition and resetting the MOSFET 121 to its normal operating condition by switching the ferroic material of the ferroic bridge 136 from the crystalline (conductive) state back to the amorphous (non-conductive) state. Broadly, an electric field applied to the reset terminal 140 (e.g., after the MOSFET 121 is latched OFF at the threshold temperature through thermal annealing) causes the ferroic material to switch back to its amorphous state so the gate-source short is removed and the MOSFET 121 is returned to functionality. The electric field may be applied perpendicular to the polarization of the ferroic material.

The gate-driving circuit 142 may drive the gate 134 and may send an electrical interrupt signal when the ferroic material switches to the electrically conducting crystalline state and thereby electrically connects the source 124 and the gate 134. The microcontroller 144 may receive the electrical interrupt signal from the gate-driving circuit 140 and send the reset signal to the reset terminal 140. In more detail, the gate-driving circuit 142 may be used to supervise the latch and non-latch states through current monitoring. Once the FET 121 is switched, the gate 134 is charged and the gate current (leakage) becomes minimal. During this driving period the voltage is maintained only to keep the FET 121 in the ON state and the gate current is continuously monitored. If the example FET 121 becomes latched by a thermal runaway, the gate sinks current spikes and the gate-driving circuit 142 latches to the OFF state and this indication of a failure is transmitted in the form of an interrupt to a microcontroller 144. Alternatively, the gate-driving circuit 142 can be a current generator, rather than a voltage source, with a specific current pulse profile to charge the gate 134 faster and then to maintain a small current which keeps the FET 121 in the ON state. In the second region, the gate-driving circuit 142 becomes a voltage source with current limited capabilities.

In operation, when thermal runaway occurs and the ferroic bridge 136 reaches the threshold temperature to switch states, the ferroic material switches from the electrically non-conductive amorphous state to the electrically conductive crystalline state and thereby electrically connects, or shorts, the source 124 and the gate 134 and causes the charge carriers to stop moving and electrical current to stop flowing through the channel 132. The gate-driving circuit 142 is latched OFF when the current monitoring threshold is reached (due to the short), and the "fault" state is indicated and the FET 121 remains in the OFF state until the next controlling cycle. During the next controlling cycle, the microcontroller 144 applies a voltage to the reset terminal 140 that switches the ferroic material back to the electrically non-conductive amorphous state, which disconnects the source 124 from the gate 134 and causes charge carriers to start moving and electrical current to start flowing through the channel 132 as the FET 121 is turned back ON. The gate-driving circuit 142 current limit threshold decreases as the gate capacitance is charged, and the gate 134 remains biased at the gate voltage and the current is continuously monitored.

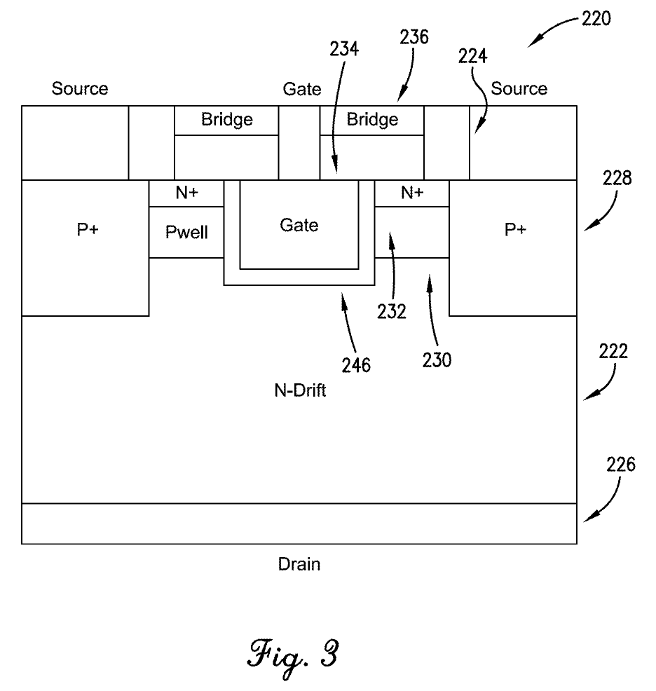

Referring to FIG. 3, a third example power MOSFET 220 with a fail-open safety feature may be substantially similar or identical to the first example MOSFET 20, including a volume of semiconductor material 222, a source 224, a drain 226, a body 228, a well 230, a channel 232, a gate 234, and a ferroic bridge 236. While the first and second example MOSFETs 20, 121 have a planar configuration, the third example gate MOSFET 220 has a trench configuration. More particularly, the gate 234 is positioned within a trench 246 formed in the volume of semiconductor material 222.

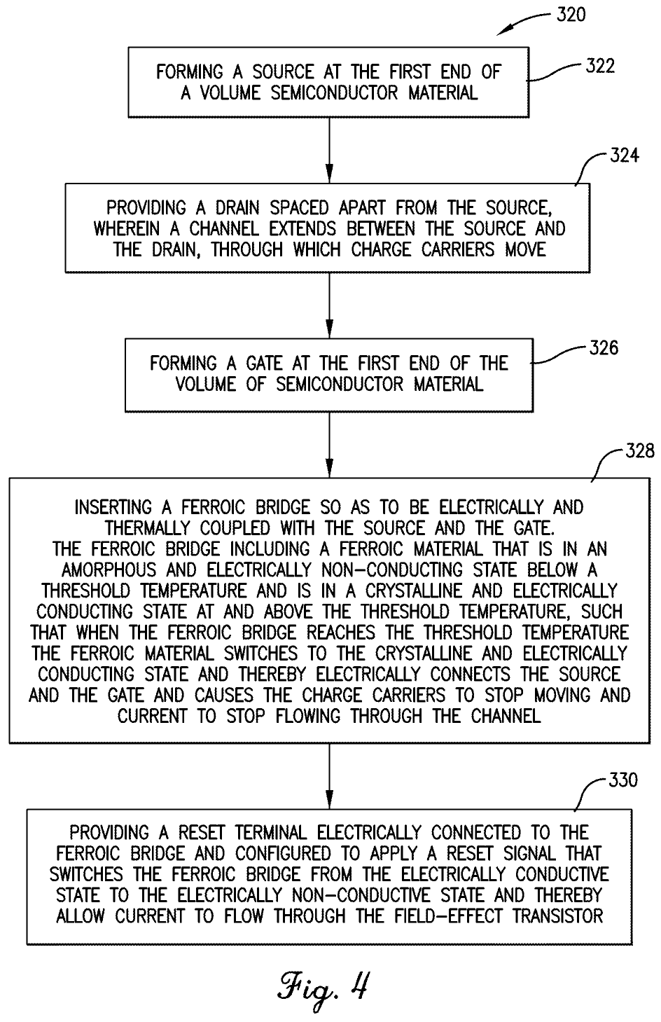

Referring to FIG. 4, an example of a method 320 of making a power MOSFET with a reversible or non-reversible fail-open safety feature, such as the example power MOSFETs 20, 121, 220 of FIGS. 1-3, to which reference is made, may include the operations set forth below. The power MOSFET 20, 121, 220 may include a volume of semiconductor material 22, 122, 222 including a first end and a second end.

A source 24, 124, 224 may be implanted or otherwise formed at the first end of the volume of semiconductor material 22, 122, 222, through which charge carriers enter, as shown in 322. A drain 26, 126, 226 may be provided spaced apart from the source 24, 124, 224 (e.g. at the second end of the volume of semiconductor material 22, 122, 222), through which the charge carriers exit, as shown in 324. A channel 32, 132, 232 may be provided by a region of the semiconductor material 22, 122, 222 between the source 23, 124, 224 and the drain 26, 126, 226, through which the charge carriers move. A gate 34, 134, 230, may be deposited or otherwise formed at the first end of the volume of semiconductor material 22, 122, 222 for facilitating control of movement of the charge carriers through the channel 32, 132, 232, as shown in 326.

A ferroic bridge 36, 136, 236 may be implanted, deposited, or otherwise inserted between the source 24, 124, 224 and the gate 34, 134, 234, as shown in 328. The ferroic bridge 36, 136, 236 may include a ferroic material that is in an amorphous and electrically non-conducting state below a threshold temperature and is in a crystalline and electrically conducting state at and above the threshold temperature, such that when the ferroic bridge 36, 136, 236 reaches the threshold temperature the ferroic material switches to the crystalline and electrically conducting state and thereby electrically connects the source 24, 124, 224 and the gate 34, 134, 234 and restricts charge carriers from moving and current from flowing through the channel 32, 132, 232. The power MOSFET may have a planar configuration (as shown in FIGS. 1 and 2) or a trench configuration (as shown in FIG. 3).

Example ferroic materials include indium (III) selenide (In₂Se₃), bis(tellanylidene)molybdenum (MoTe₂), tin(II) sulfide (SnS), perovskite (CaTiO₃), poly(1,1-difluoroethylene) (C₂H₂F₂), hafnium(IV) oxide (HfO₂), tin telluride (SnTe), germanium selenide (GeSe), copper indium phosphorous sulfide (CuInP₂S₆) (also called "CIPS"), bismuth oxide selenide (Bi₂O₂Se), and combinations thereof. In some examples, the ferroic material may be undoped. In other examples, the ferroic material may be doped with a suitable dopant for changing the crystallization temperature for the ferroic material. Example dopants include ZN, silicon dioxide (SiO₂), titanium (Ti), nitrogen (N), antimony (Sb), and sulfur (S), and combinations thereof. The temperature threshold may depend on the ferroic material and, if present, the doping material and the doping percentage. The threshold temperature may be above a normal operating temperature of the MOSFET 20, 121, 220 and below a critical temperature at which a structural failure of the MOSFET 20, 121, 220 may occur.

The method 320 may further include providing a reset terminal 140, or reset gate, electrically connected to the ferroic bridge 136 and configured to apply a reset signal that switches the ferroic bridge 136 from the electrically conductive state to an electrically non-conductive state to thereby allow current to flow through the MOSFET 20, 121, 220, as shown in 330 and seen in FIG. 2. The electrical signal may be applied perpendicular to a polarization of the ferroic bridge 136. The reset terminal 140 may be electrically connected to a gate-driving circuit 142 and a microcontroller 144 which may be used to supervise the latch and non-latch states through current monitoring, as described above. Additional processing may be performed as desired.

Although described herein with regard or in relation to one or more particular kinds of electronic devices (e.g., junction field-effect transistors, metal oxide semiconductor field-effect transistors), the technology may be more broadly applicable to one or more other kinds of electronic devices as well. One with ordinary skill in the art will recognize that the technology described herein may, when applicable, be implemented in enhancement mode or depletion mode. Further, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, gate material may include polysilicon, a metal or alloy of metals, or other suitable material; gate oxide or dielectric may include silicon dioxide, aluminum oxide, hafnium dioxide, silicon nitride, or other suitable material; and semiconductor material may include silicon, silicon carbide, gallium nitride, zinc oxide, or other suitable material.

Additionally, in general, unless otherwise specified or unless one with ordinary skill in the art would understand otherwise, doping concentrations for contact implants may be approximately between ten to the power of eighteen (10^18) and ten to the power of twenty two (10^22); doping concentrations for channel and threshold forming implants may be approximately between ten to the power of sixteen (10^16) and ten to the power of seventeen (10^17); doping concentrations for shielding implants may be approximately between ten to the power of seventeen (10^17) and ten to the power of nineteen (10^19); and doping concentrations for conductivity improvement implants (e.g., N- doping in the junction field-effect transistor neck region of a metal oxide semiconductor field-effect transistor) may be approximately between ten to the power of sixteen (10^16) and ten to the power of seventeen (10^17). Relatedly, a structure or region may contain two or more different doping doses. For example, one with ordinary skill in the art will recognize that some P-wells may contain a lower dose P-well portion and a higher dose unclamped inductive switching portion.

Additionally, although only one or a few instances of a device or apparatus may be described herein, it will be appreciated that some applications may involve many such devices or apparatuses, which may be different from, substantially similar to, or identical to the described device or apparatus, and which may be arranged (e.g., in an array) on a larger extension of the volume of semiconductor material. In that light, references to a right and/or left side of a volume of semiconductor material may be to the conceptual limit of a particular unit cell and not to an actual physical end of the material.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

1. A field-effect transistor comprising:
a source;
a gate; and
a ferroic bridge electrically and thermally coupled with the source and the gate, the ferroic bridge switching from an electrically non-conducting state to an electrically conducting state at a threshold temperature to thereby electrically connect the source and the gate and restrict an electrical current from flowing through the field-effect transistor.

2. The field-effect transistor of claim 1, wherein the field-effect transistor has a trench configuration.

3. The field-effect transistor of claim 1, wherein the ferroic bridge includes a ferroic material selected from the group consisting of: indium (III) selenide (In₂Se₃), bis(tellanylidene)molybdenum (MoTe₂), tin(II) sulfide (SnS), perovskite (CaTiO₃), poly(1,1-difluoroethylene) (C₂H2F₂), hafnium(IV) oxide (HfO₂), tin telluride (SnTe), germanium selenide (GeSe), copper indium phosphorous sulfide (CuInP₂S₆), bismuth oxide selenide (Bi₂O₂Se), and combinations thereof.

4. The field-effect transistor of claim 3, wherein the ferroic material is doped with a dopant selected from the group consisting of: zinc (ZN), silicon dioxide (SiO₂), titanium (Ti), nitrogen (N), antimony (Sb), sulfur (S), and combinations thereof.

5. The field-effect transistor of claim 1, wherein the ferroic bridge includes a ferroic material doped with a dopant selected from the group consisting of: zinc (ZN), silicon dioxide (SiO₂), titanium (Ti), nitrogen (N), antimony (Sb), sulfur (S), and combinations thereof.

6. The field-effect transistor of claim 1, wherein the ferroic bridge includes a ferroic material that is in an electrically non-conducting amorphous state below the threshold temperature, and is in an electrically conducting crystalline state at and above the threshold temperature.

7. The field-effect transistor of claim 6, wherein the threshold temperature is above a normal operating temperature of the field-effect transistor and below a critical temperature at which a structural failure of the field effect transistor occurs.

8. The field-effect transistor of claim 6, wherein the ferroic material is selected from the group consisting of: indium (III) selenide (In₂Se₃), bis(tellanylidene)molybdenum (MoTe₂), tin(II) sulfide (SnS), perovskite (CaTiO₃), poly(1,1-difluoroethylene) (C₂H2F₂), hafnium(IV) oxide (HfO₂), tin telluride (SnTe), germanium selenide (GeSe), copper indium phosphorous sulfide (CuInP₂S₆), bismuth oxide selenide (Bi₂O₂Se), and combinations thereof.

9. The field-effect transistor of claim 6, wherein the ferroic material is doped with a dopant selected from the group consisting of: zinc (ZN), silicon dioxide (SiO₂), titanium (Ti), nitrogen (N), antimony (Sb), sulfur (S), and combinations thereof.

10. The field-effect transistor of claim 1, wherein the threshold temperature is above a normal operating temperature of the field-effect transistor and below a critical temperature at which a structural failure of the field effect transistor occurs.

11. A metal oxide semiconductor field-effect transistor device comprising:
a metal oxide semiconductor field-effect transistor including –
a volume of semiconductor material,
a source located at a first end of the volume of semiconductor material and through which charge carriers enter,
a drain located spaced apart from the source and through which the charge carriers exit,
a channel located between the source and the drain and through which the charge carriers move between the source and the drain,
a gate located at the first end of the volume of semiconductor material used in controlling movement of the charge carriers through the channel, and
a ferroic bridge electrically coupled with the source and the gate,
the ferroic bridge including a ferroic material that is in an electrically non-conducting state below a threshold temperature and in an electrically conducting state at and above the threshold temperature, such that when the ferroic bridge reaches the threshold temperature the ferroic material switches to the electrically conducting state to thereby electrically connect the source and the gate and restrict the charge carriers from moving and an electrical current from flowing between the source and the drain; and
a reset terminal electrically connected to the ferroic bridge and configured to apply a reset signal that switches the ferroic bridge from the electrically conductive state to the electrically non-conductive state to thereby permit the charge carriers to move and the electrical current to flow between the source and the drain.

12. The metal oxide semiconductor field-effect transistor device of claim 11, wherein the volume of semiconductor material presents a trench in which the gate is at least partially located.

13. The metal oxide semiconductor field-effect transistor device of claim 11, wherein the ferroic material is selected from the group consisting of: indium (III) selenide (In₂Se₃), bis(tellanylidene)molybdenum (MoTe₂), tin(II) sulfide (SnS), perovskite (CaTiO₃), poly(1,1-difluoroethylene) (C₂H2F₂), hafnium(IV) oxide (HfO₂), tin telluride (SnTe), germanium selenide (GeSe), copper indium phosphorous sulfide (CuInP₂S₆), bismuth oxide selenide (Bi₂O₂Se), and combinations thereof.

14. The metal oxide semiconductor field-effect transistor device of claim 13, wherein the ferroic material is doped with a dopant selected from the group consisting of: zinc (ZN), silicon dioxide (SiO₂), titanium (Ti), nitrogen (N), antimony (Sb), and sulfur (S), and combinations thereof.

15. The metal oxide semiconductor field-effect transistor device of claim 11, wherein the ferroic material is doped with a dopant selected from the group consisting of: zinc (ZN), silicon dioxide (SiO₂), titanium (Ti), nitrogen (N), antimony (Sb), and sulfur (S), and combinations thereof.

16. The metal oxide semiconductor field-effect transistor device of claim 11, wherein the threshold temperature is above a normal operating temperature of the metal oxide semiconductor field-effect transistor and below a critical temperature at which a structural failure of the metal oxide semiconductor field-effect transistor occurs.

17. The metal oxide semiconductor field-effect transistor device of claim 11, wherein the ferroic material is in an electrically non-conducting amorphous state below the threshold temperature, and is in an electrically conducting crystalline state at and above the threshold temperature.

18. The metal oxide semiconductor field-effect transistor device of claim 11, comprising:
a gate-driving circuit configured to drive the gate and send an electrical interrupt signal when the ferroic material switches to the electrically conducting state to thereby electrically connect the source and the gate; and
a microcontroller configured to receive the electrical interrupt signal from the gate-driving circuit and send the reset signal to the reset terminal.

19. The metal oxide semiconductor field-effect transistor device of claim 11, wherein the reset signal is applied perpendicular to a polarization of the ferroic bridge.

20. The metal oxide semiconductor field-effect transistor device of claim 19, comprising:
a gate-driving circuit configured to drive the gate and send an electrical interrupt signal when the ferroic material switches to the electrically conducting state to thereby electrically connect the source and the gate; and
a microcontroller configured to receive the electrical interrupt signal from the gate-driving circuit and send the reset signal to the reset terminal.
